(19) United States
(12) Patent Application Publication
(10) Pub. No.: US 2025/0343108 A1
(43) Pub. Date: Nov. 6, 2025

(54) THROUGH-SILICON-VIA ANNULAR GUARD RING

(71) Applicant: International Business Machines Corporation, Armonk, NY (US)

(72) Inventors: Mukta Ghate Farooq, HOPEWELL JCT, NY (US); James J. Kelly, Schenectady, NY (US)

(21) Appl. No.: 18/655,569

(22) Filed: May 6, 2024

(51) Int. Cl. H01L 23/48; H01L 23/58

(52) U.S. Cl. CPC H01L 23/481; H01L 23/585

(57) ABSTRACT

A semiconductor structure with an annular guard ring extending through an interlayer dielectric (ILD) layer to a top surface of a semiconductor substrate. The annular guard ring surrounds a through-silicon-via (TSV). The annular guard ring is composed of layer of a liner material around a dielectric material.

### BACKGROUND

The disclosure generally relates to forming semiconductor devices, and more specifically, to a method of forming through-silicon-vias and the resulting structure.

Through-silicon vias (TSVs) are electrical interconnects that are etched into a silicon wafer. TSVs can also be referred to as through-wafer vias. The primary benefit that comes from the use of TSVs is reduced interconnect length with short vertical connections through thinned silicon die. The TSV's enable reduced latency, lower capacitance, lower inductance and permits higher speed communications, higher numbers of interconnections, and lower power level communication links between circuits. The use of thinned wafers with TSVs and stacked semiconductor chips with TSVs permit the miniaturization of integrated multi-chip systems. Several types of TSVs have been created to address different design and performance requirements. Several methods of forming TSVs have evolved including via first, via middle, or via last. In the via first method, the TSVs are created in the semiconductor wafer before the active circuitry is fabricated on the silicon wafer. In TSVs formed with the via first method, the TSVs are connected to the integrated circuits' active layers. In via middle method, the TSVs are created after the active circuitry is fabricated using front-end-of-line semiconductor processes but before the back-end-of-line fabrication of interconnect metallization layers above the active circuits. The middle via approach is primarily used to connect both the active and passive layers of the integrated circuits through TSVs. In via last method, the TSVs are fabricated after the fabrication of active layers and after the front side interconnect wiring layers are formed using back-end-of-line semiconductor processes. For the TSVs formed in with the via last method, the TSVs can connect to the next level of packaging such as external package or another semiconductor substrate when stacking semiconductor chips.

### SUMMARY

Embodiments of the invention include a semiconductor structure that includes an annular guard ring extending through an interlayer dielectric (ILD) layer to a top surface of a semiconductor substrate. The structure further includes that the annular guard ring surrounds a through-silicon-via (TSV). The structure further includes that the annular guard ring is composed of layer of a liner material around a dielectric material.

Embodiments of the invention include a semiconductor structure that includes an annular guard ring extending through an interlayer dielectric (ILD) layer to a top surface of a semiconductor substrate. The structure further includes that the annular guard ring surrounds a through-silicon-via (TSV). The structure further includes that the annular guard ring is composed of a first liner layer, a first dielectric material layer, a second liner layer, and a second dielectric material.

Embodiments of the invention include a method for fabricating a semiconductor device. The method includes forming an annular trench within an interlayer dielectric (ILD) layer, wherein the annular trench exposes a top surface of a substrate. The method can also include forming a liner material layer on exposed surfaces of the ILD layer and the substrate. The method can also include removing portions of the liner material layer that are external to the annular trench. The method can also include forming a dielectric material layer within the annular trench.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a top view of a portion of the semiconductor structure of an annular guard ring around a through-silicon-via (TSV) via hole, in accordance with an embodiment of the present invention.

FIG. 2 depicts a cross-sectional view of a semiconductor structure after forming front side interconnect wiring, in accordance with an embodiment of the present invention.

FIG. 3 depicts a cross-sectional view of the semiconductor structure after etching a trench for an annular guard ring, in accordance with an embodiment of the present invention.

FIG. 4 depicts a cross-sectional view of a semiconductor structure after depositing a liner material in the trench for the annular guard ring, in accordance with an embodiment of the present invention.

FIG. 5 depicts a cross-sectional view of the semiconductor structure after depositing a dielectric isolation material inside the nitride liner and planarizing the top surface of the semiconductor substrate to form the annular guard ring, in accordance with an embodiment of the present invention.

FIG. 6 depicts a cross-sectional view of the semiconductor structure after etching a top portion of the TSV via hole in an interlayer dielectric (ILD) of the front side interconnect wiring and etching a bottom portion of the TSV via hole in the semiconductor substrate, in accordance with an embodiment of the present invention.

FIG. 7 depicts a top view of a portion of the semiconductor structure after filling the TSV via hole inside the annular guard ring, in accordance with an embodiment of the present invention.

FIG. 8 depicts a cross-sectional view of the semiconductor structure after forming front side interconnect wiring, etching a trench for an annular guard ring, and depositing a first layer of a nitride liner material, a first dielectric isolation material, a second layer of a nitride liner metal material, and a second dielectric isolation material for a multilayer annular guard ring, in accordance with an embodiment of the present invention.

FIG. 9 depicts a cross-sectional view of the semiconductor structure after etching a top portion of a TSV via hole in the ILD of the front side interconnect wiring, etching a bottom portion of the TSV via hole in the semiconductor substrate, and filling the TSV via hole, in accordance with an embodiment of the present invention.

FIG. 10 depicts a top view of the multilayer annular guard ring in a center portion of the semiconductor structure of FIG. 9, in accordance with an embodiment of the present invention.

### DETAILED DESCRIPTION

As known to one skilled in the art, moisture penetration into one or more layers of the front side interconnect wiring during through-silicon-via formation reduces back-end-of-line (BEOL) semiconductor yields and creates reliability concerns for the integrity of the front side interconnect wiring. Methods and semiconductor structures that prevent moisture ingress into the front side interconnect wiring during TSV silicon etching and metal deposition processes are advantageous for front side interconnect wiring reliability.

Embodiments of the present invention provide a semiconductor structure that includes an annular guard ring formed in the frontside interconnect wiring above the semiconductor substrate around the location of a through-silicon-via (TSV). In embodiments of the present invention, the annular guard ring is composed of a layer of a liner material deposited in a trench and filled with a dielectric material. The annular guard ring around a top portion of a through-silicon-via hole. The annular guard ring and the top portion of the through-silicon via are above and reside on the semiconductor substrate. The annular guard ring protects the layers of the front side interconnect wiring adjacent to the top portion of the through-silicon-via hole from moisture and chemical ingress during the semiconductor substrate etching processes to form the bottom portion of a via-last through-silicon via hole. Reducing or preventing moisture and chemical ingress into one or more layers of the front side interconnect wiring during the etching of the bottom portion of the through-silicon via and the various lining and metal fill processes associated with completing the through-silicon-via reduces semiconductor chip yield loss.

The trench for the forming the annular guard ring is etched around the location of the future TSV. The liner material on the sidewalls and bottom surface of the trench. The annular guard ring includes dielectric fill material inside the liner material. The liner material and deposited dielectric fill material are removed, for example, by a chemical-mechanical polish, from the top surface of the front side interconnect wiring and interlayer dielectric around a top portion of a via hole, such as but not limited to, the top portion of a through-silicon-via hole. The through-silicon via and through-silicon via hole have a horizontal cross-section that is essentially circular, oval, or rectangular in shape. Accordingly, the annular guard ring around the top portion of the TSV via or TSV via hole can have a horizontal cross-section with an essentially circular, oval, or rectangular in shape.

The portion of the interlayer dielectric (ILD) in the location of the future TSV does not have any portions of a layer of metal from the front side interconnect wiring. In embodiments, the annular guard ring, as viewed from the top surface of the semiconductor structure, forms two essentially concentric circular or oval-shaped rings of the liner material that surround a ring of dielectric material inside the two rings of the liner material. In some embodiments, the annular guard ring when viewed from the top includes concentric rectangular rings of the liner material around the of dielectric material.

The annular guard ring can have a depth extending from the top surface of the front side interconnect wiring to the top surface of the semiconductor substrate. The annular guard ring can have essentially vertical sidewalls and a bottom surface on the top of the semiconductor substrate. The annular guard ring, formed after the back-end-of-line (BEOL) fabrication processes creating the front side interconnect wiring but before etching the TSV via hole can prevent or reduce moisture and/or chemicals used during TSV formation from entering into one or more layers of the front side interconnect wiring during TSV formation. Preventing moisture migration into the front side interconnect wiring during TSV formation can both improve the resulting semiconductor chip reliability and, improve the BEOL yields.

The trench around the location of a future TSV can be etched after forming the front side interconnect wiring during BEOL semiconductor processes. Depositing a liner material such as a nitride material on the exposed surfaces of the trench and the top surface of the semiconductor structure. The dielectric material can be deposited on the liner material filling the trench. A CMP can remove excess liner material and dielectric material from the top surface of the semiconductor substrate. As previously discussed, the annular guard ring composed of the liner material and dielectric material residing on the semiconductor substrate forms a moisture barrier around the location of a future TSV. In embodiments of the present invention, the annular guard ring is formed after front side interconnect wiring and before etching the top portion of a TSV via hole in the center of the annular guard ring.

Embodiments of the present invention provide a semiconductor structure with a multilayer annular guard ring around the top portion of a TSV. The multilayer annular guard ring also resides in a portion of the ILD without metal interconnect wiring. Similar to the annular guard ring, the multilayer annular guard ring surrounds the portion of ILD without metal layers around the location a TSV. The multilayer annular guard ring extends from the top surface of the front side interconnect wiring to the top surface of the semiconductor substrate.

In embodiments of the present invention, the multilayer annular guard ring is composed of a first layer of a liner material on the sidewall and bottom surface of a trench with a layer of the first dielectric material on the first layer of the liner material, a second layer of the liner material is deposited on the layer of the first dielectric material, and a second dielectric material fills the area between the sidewalls of the second liner material. The trench is etched around a location of a future TSV after forming the front side interconnect wiring and before TSV via hole etching. Viewed from the top, the multilayer annular guard ring is a number of concentric rings of composed of the first liner material, the first dielectric material, the second liner material, the second dielectric, the second liner material, the first dielectric material, and the first liner material that surround a ring of ILD around the TSV. The TSV via hole is etched in the center of the concentric rings of the multilayer annular guard ring and then, filled. In some embodiments, when viewed from the top, the concentric rings can have an essentially circular or rectangular shape around the TSV.

The multilayer annular guard ring, similar to the annular guard ring, is formed after BEOL fabrication processes and before the TSV formation processes. The multilayer annular guard ring can prevent moisture or chemical ingress into one or more layers of the front side interconnect wiring during the semiconductor substrate etching to form the bottom portion of the TSV via hole in the semiconductor substrate. By preventing or reducing the moisture penetration into the layers of the front side interconnect wiring, the multilayer annular guard can reduce BEOL yield losses and improve the semiconductor chip reliability. Compared to the annular guard ring, the multilayer annular guard ring may provide better protection of the front side interconnect wiring from moisture penetration during TSV formation.

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Some of the process steps, depicted, can be combined as an integrated process step. In addition, descriptions of well-known functions and constructions may be omitted for clarity and conciseness.

The terms and words used in the following description and claims are not limited to the bibliographical meanings but are merely used to enable a clear and consistent understanding of the invention. Accordingly, it should be apparent to those skilled in the art that the following description of exemplary embodiments of the present invention is provided for illustration purposes only and not for the purpose of limiting the invention as defined by the appended claims and their equivalents.

It is to be understood that the singular forms “a,” “an,” and “the” include plural referents unless the context dictates otherwise. Thus, for example, reference to “a component surface” includes reference to one or more of such surfaces unless the context dictates otherwise.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “on”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” or “contact” means that a first element, such as a first structure, and a second element, such as a second structure, are connected without any intermediary conducting, insulating, or semiconductor layers at the interface of the two elements.

In the interest of not obscuring the presentation of embodiments of the present invention, in the following detailed description, some processing steps or operations that are known in the art may have been combined for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Reference will now be made in detail to the embodiments of the present invention, examples of which are illustrated in the accompanying drawings, wherein like reference numerals refer to like elements throughout.

Deposition processes for materials, such as metal materials, dielectric materials, and sacrificial materials include but are not limited to chemical vapor deposition (CVD), physical vapor deposition (PVD), atomic layer deposition (ALD), molecular layer deposition (MLD), high-density plasma (HDP) deposition, or gas cluster ion beam (GCIB) deposition. Variations of CVD processes include but are not limited to, atmospheric pressure CVD (APCVD), low-pressure CVD (LPCVD), plasma enhanced CVD (PECVD), and metal-organic CVD (MOCVD), and combinations thereof may also be employed.

Removal, removing, or etching as used herein includes but is not limited to patterning using one of lithography, photolithography, an extreme ultraviolet (EUV) lithography process, or any other known semiconductor patterning process (e.g., patterning a resist or an organic planarization layer) followed by one or more etching processes. Some examples of etching processes include but are not limited to the following processes, such as a dry etching process using a reactive ion etch (RIE) or ion beam etch (IBE), a wet chemical etch process, or a combination of these etching processes.

Reference is now made to the figures. The figures provide schematic cross-sectional illustrations of semiconductor devices at intermediate stages of fabrication, according to one or more embodiments of the invention. The device provides schematic representations of the devices of the invention and is not to be considered accurate or limiting with regard to the device element scale.

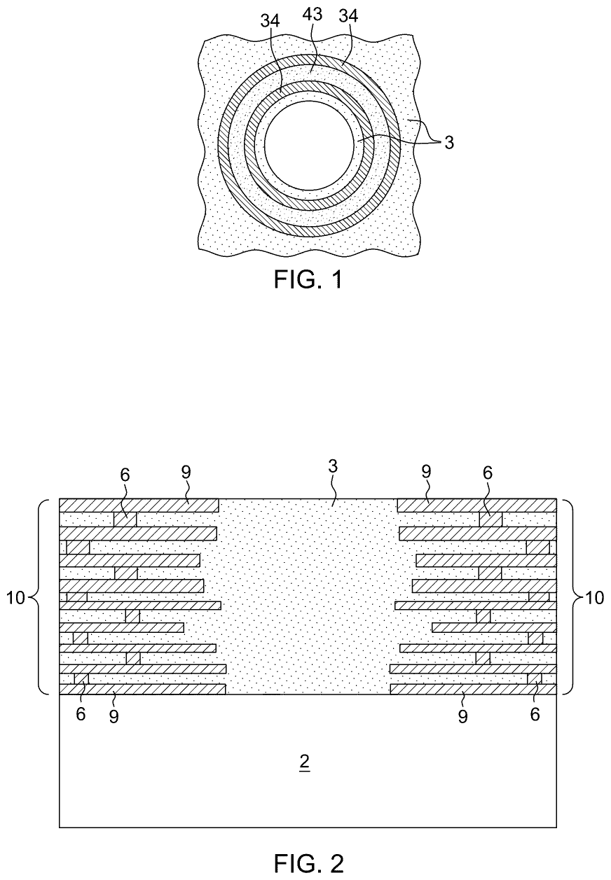

FIG. 1 depicts a top view of a portion of the semiconductor structure of an annular guard ring composed of a first outer ring of liner 34 around dielectric 43 and a second inner ring of liner 34 in ILD 3 that is around a center TSV via hole, in accordance with an embodiment of the present invention.

As depicted, FIG. 1 illustrates a top view of an embodiment of an annular guard ring composed of a layer of liner 34 surrounding a trench and filled with dielectric 43

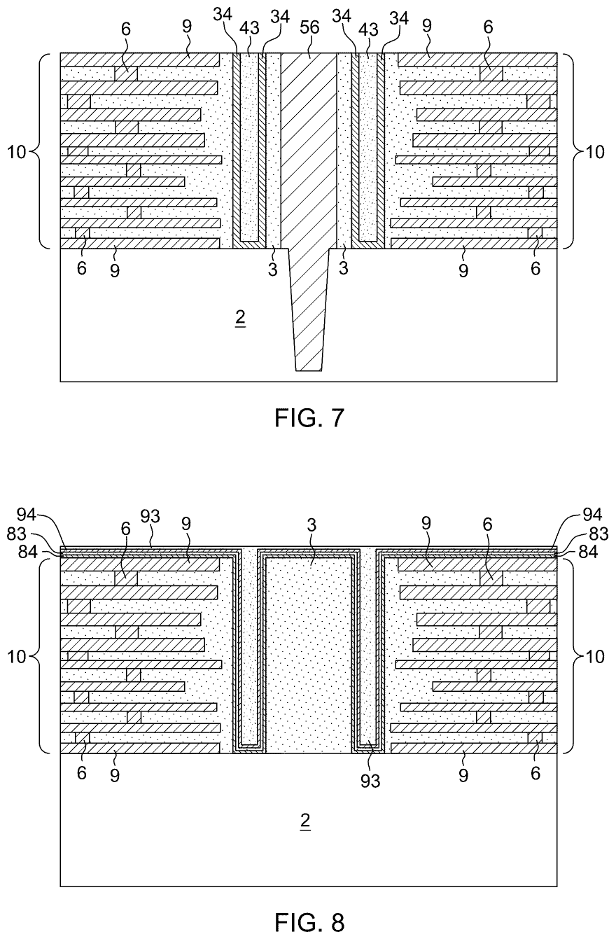

As depicted in FIG. 1, the layer of liner 34 on each of the sidewalls of the trench is around a TSV via hole. The top view of the annular guard ring includes a portion of ILD 3 outside and contacting the outer ring of liner 34. The portion of ILD 3 contacting the outer ring of liner 34 is inside of a portion of the front side interconnect wiring (not depicted in FIG. 1) without metal layers. As depicted, dielectric 43 is between the outer ring and the inner ring of liner 34 inside the trench etched around the TSV via hole. Dielectric 43 fills the area between the outer and inner ring of liner 34 on the inner sidewall of the trench around the TSV via hole and the outer sidewall of the trench around the TSV via hole. Dielectric 43 may be composed of an oxide such as SiO₂ but is not limited to these dielectric materials. The inner ring of liner 34 directly contacts a ring composed of a second portion of ILD 3 that directly surrounds the TSV via hole. The ring of the second portion of ILD 3 will isolate the TSV via hole when filled with TSV metal as depicted later in FIG. 7.

In various embodiments, liner 34 is a single layer of a liner material such as a layer of nitride material that is deposited in a circular trench. For example, liner 34 can be composed of SiNₓ, (SiNₓ:H), (SiNₓ(C)), and (SiNₓ:H(C)) but is not limited to these exact materials. In some cases, liner 34 is a combination of a nitride and an oxide such as SiOCN. The trench can be etched in a portion of ILD 3 in the front side interconnect wiring, preferably, after known back-end-of-line semiconductor fabrication processes form the front side interconnect wiring above the semiconductor devices. The trench for forming the annular guard ring can be etched around the location of a future TSV in the portion of ILD 3 without metal wiring layers. As depicted in FIG. 1, the TSV via hole is in the center of ILD 3 inside of the inner ring of liner 34. The TSV via hole can be etched in the center portion of ILD 3 after planarizing the semiconductor structure with liner 34 and dielectric 43. In some embodiments, the top view of the annular guard ring composed of liner 34 and dielectric 43 forms a rectangular shape (e.g., the annular guard ring can form a rectangular tube around the TSV via hole). In an embodiment, the top view of the annular guard ring depicts the annular guard ring with an oval shape around the TSV via hole.

In some embodiments, the annular guard ring composed of one or more layers of liner 34 and dielectric 43 is around a location of a future power via or a power rail before etching the portion of the power via and/or power rail extending through substrate 2. The annular guard ring in the front side interconnect wiring adjacent to a portion of a power via or a power rail that will later be etched into the semiconductor substrate can prevent moisture or chemical ingress into one or more layers of front side interconnect wiring 10.

FIG. 2 depicts a cross-sectional view of a semiconductor structure after forming front side interconnect wiring 10, in accordance with an embodiment of the present invention. As depicted in FIG. 1, front side interconnect wiring 10 is formed above semiconductor substrate 2 and the semiconductor devices (not depicted). Substrate 2 can be composed of silicon or any other known semiconductor substrate or wafer material used in the fabrication of semiconductor devices.

As known to one skilled in the art, front side interconnect wiring 10 is formed using known back-end-of-line (BEOL) semiconductor fabrication processes and can be composed of numerous metal layers 9 that are vertically connected by one or more of vias 6. Metal layers 9 can be electrically isolated by one or more layers of ILD 3. It is understood that in addition to the BEOL features 6 and 9, other features comprising middle of line or other device structures may also be contained in 10 and be placed on top of substrate 2.

While FIG. 1 depicts nine horizontal metal layers 9 each connected by at least one of vias 5, in other examples, any number metal layers 9 and vias 6 can be present in other examples. In FIG. 1, a center portion of front side interconnect wiring 10 does not depict metal layers 9 or vias 6. The center portion of front side interconnect wiring 10 composed of only ILD 3. The center portion of FIG. 2 including only ILD 3 can be the location of a future filled TSV and an annular guard ring (depicted later in FIG. 7).

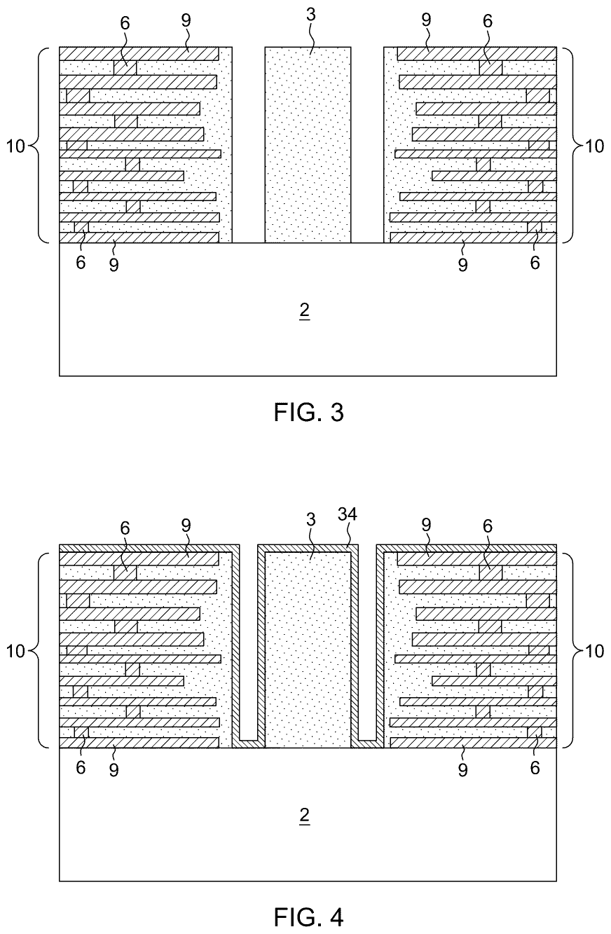

FIG. 3 depicts a cross-sectional view of the semiconductor structure after etching a trench for an annular guard ring, in accordance with an embodiment of the present invention. As depicted, FIG. 2 includes the elements of FIG. 1 without a portion ILD 3 above semiconductor substrate 2 around the center area of ILD 3 in FIG. 2.

Using known semiconductor fabrication processes for trench etching in a dielectric material, the trench around the center portion of FIG. 2 can be formed. For example, using known semiconductor processes such as lithograph patterning of a resist or organic planarization layer (OPL) and a dry etching process (e.g., RIE) or wet etching process, the trench is formed in ILD 3 inside of the center area of where metal layers 9 in front side interconnect wiring 10 are not present.

The trench around the center ILD 3 surrounds the location where a TSV will be formed. The trench around the location of the future TSV can have any shape. For example, the trench can form a ring, a rectangle, or an oval around the location of a future TSV. As depicted in FIG. 3, the trench can be around the middle portion of FIG. 3 in ILD 3 and inside of front side interconnect wiring 10. The trench may be inside of metal layers 9 of front side interconnect wiring 10 and in a portion of the center ILD 3 where no metal layers 9 are present. The etching process forming the trench stops on the top surface of semiconductor substrate 2. In various embodiments, the sidewalls and bottom surface of the trench create a circular opening or ring around the location of the future TSV in the center of FIG. 3.

A typical width of the trench may be one to ten microns but is not limited to these widths. For example, the width of the trench can vary depending on the depth of the etched trench (e.g., can vary depending on the number of metal layers in front side interconnect wiring 10). The aspect ratio of the etched trench can typically range from three to four but is not limited these aspect ratios. An aspect ratio is the ratio between the depth of a hole and the diameter of a hole. In this case, the diameter of the hole would be the width of the trench.

FIG. 4 depicts a cross-sectional view of a semiconductor structure after depositing liner 34 in the trench for the annular guard ring, in accordance with an embodiment of the present invention. As depicted, FIG. 4 includes the elements of FIG. 3 with the addition of a layer of liner 34 on the exposed top surfaces of the semiconductor structure.

Using one or more known deposition processes such as but not limited to CVD, ALD or a high-density plasma process, a layer of liner 34 can be deposited on the sidewalls and bottom surface of the trench, and on the exposed top surface of semiconductor structure (e.g., on ILD 3 and metal layer 9 of front side interconnect wiring 10 as depicted). For example, the thickness of the layer of liner 34 can range from 50 to 500 nm but is not limited to these thicknesses. In various embodiments, liner 34 is composed of a nitride liner material. The nitride liner material can be SiNₓ, (SiNₓ:H), (SiNₓ(C)), and (SiNₓ:H(C)), for example, but is not limited to these nitride liner materials. In other embodiments, liner 34 is a multilayer liner material. For example, liner 34 can be composed of one or more layers of different nitride liner materials or a combination of a nitride liner material.

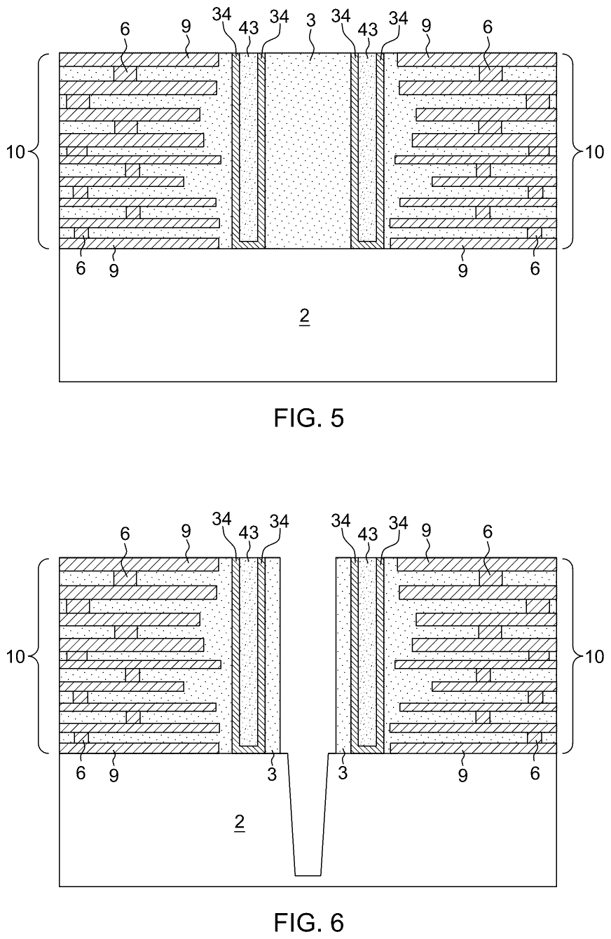

FIG. 5 depicts a cross-sectional view of the semiconductor structure after depositing a dielectric 43 inside and on liner 34 and planarizing the top surface of the semiconductor substrate, in accordance with an embodiment of the present invention. As depicted, FIG. 5 includes the elements of FIG. 4 with the addition of dielectric 43 and without the top portion of liner 34 on front side interconnect wiring 10 and ILD 3.

Using a deposition process such as PECVD, SACVD, ALD, or a flowable oxide material, dielectric 43 is deposited on the exposed surfaces of the semiconductor structure and fills the trench (e.g., contacts both sidewalls of liner 34 and fills the opening between the sidewalls of liner 34). The deposition method for dielectric 43 can be selected based, at least in part, on the aspect ratio of the trench opening. In various embodiments, dielectric 43 is an oxide material. For example, dielectric 43 can be SiO₂ but dielectric 43 is not limited to an oxide dielectric material and in other examples can be composed of a different dielectric material.

In various embodiments, after depositing dielectric 43, a CMP planarizes the top surface of the semiconductor structure. The CMP removes excess liner 34 and dielectric 43 on the top surface of front side interconnect wiring 10 and ILD 3 while leaving the portions of liner 34 and dielectric 43 in the filled trench around the location of the future TSV. In an embodiment and as an alternative to CMP, a timed anisotropic etch (e.g., RIE) removes the horizontal top portion of liner 34 and dielectric 43 on the semiconductor structure, stopping at the top surface of front side interconnect wiring 10.

As depicted in FIG. 5, the annular guard ring inside of front side interconnect wiring 10 is around the location of a future formed TSV. The future TSV will be formed in ILD 3 in the center of FIG. 5. In various embodiments, the annular guard ring around the location of the future TSV can be composed of a core of dielectric 43 inside the layer of liner 34. The layer of liner 34 resides on the sidewalls and bottom surface of the filled trench. As depicted in FIG. 5, the annular guard ring is inside the portions of metal layers 9 in front side interconnect wiring 10 surrounding the central portion of ILD 3 in the location of the future TSV. As previously discussed, the annular guard ring composed of liner 34 and dielectric 43 reduces or prevents the ingress of moisture or semiconductor etching chemicals during and after etching substrate 2 to form the bottom portion of the TSV via hole in later TSV fabrication processes.

FIG. 6 depicts a cross-sectional view of the semiconductor structure after etching a top portion of the TSV via hole in an interlayer dielectric (ILD) of the front side interconnect wiring and etching a bottom portion of the TSV via hole in the semiconductor substrate, in accordance with an embodiment of the present invention. As depicted, FIG. 6 includes the elements of FIG. 5 without a portion of the center ILD 3 and without a portion of semiconductor substrate 2 under the removed ILD 3.

The top portion of the TSV via hole is etched through ILD 3 stopping on the top surface of semiconductor substrate 2 using known BEOL etching processes (e.g., patterning and RIE) for forming the top portion of a via last TSV via hole. After completing the etching of the top portion of the TSV via hole, a portion of ILD 3 remains around the sidewall of the top portion of the TSV via hole and liner 34. The remaining portion of the center ILD 3 can electrically isolate liner 34 from the future TSV.

After etching the top portion of the TSV via hole above semiconductor substrate 2, using known TSV semiconductor etching processes (e.g., RIE and/or IBE), the bottom portion of the TSV via hole is formed in semiconductor substrate 2. In various embodiments, the bottom portion of the TSV via hole does not extend to the bottom surface of semiconductor substrate 2 (e.g., forms a blind via hole). As depicted, the bottom portion of the TSV via hole extends from the top surface of semiconductor substrate 2 to a bottom region of semiconductor substrate although in other examples, the depth of the bottom portion of the TSV via hole may be less or greater than the depth of the TSV via hole in FIG. 6.

FIG. 7 depicts a top view of a portion of the semiconductor structure after filling the TSV via hole, in accordance with an embodiment of the present invention. As depicted, FIG. 7 includes the elements of FIG. 6 with the addition of TSV fill 56. As depicted, FIG. 7 includes the elements of FIG. 6 with the addition of TSV fill 56.

Using known TSV fabrication processes, the TSV via hole can be filled with a conductive metal fill, such as but not limited to copper. As known to one skilled in the art, the process of filling the TSV via hole with TSV fill 56 includes at least a TSV insulating liner (not depicted) deposited on the sidewall of both the top portion and the bottom portion of the TSV via hole, a barrier layer (not depicted), a seed layer (not depicted), and TSV fill 56 on the seed layer on the TSV insulating liner. TSV fill 56 that fills the TSV via hole as depicted in FIG. 7. TSV fill 56, typically copper, can be deposited by one or more known deposition processes (e.g., ALD, CVD, PVD, PECVD, electroplating or a combination of these) inside the TSV via hole. For example, TSV fill 56 which includes at least a TSV insulating liner, a barrier layer, seed layer, and conductive metal fill (e.g., copper) fill the TSV via hole. A CMP may be performed to planarize the top surface of the semiconductor structure and remove any excess TSV fill 56.

As depicted, TSV fill 56 resides inside a ring of ILD 3 separating and electrically isolating liner 34 from TSV fill 56. The annular guard ring composed of liner 34 surrounding a core of dielectric 43 reduces or prevents the moisture or substrate 2 etching chemicals from entering the layers of front side interconnect wiring 10 during the etching of the bottom portion of TSV via hole and subsequent deposition processes for TSV fill 56. As depicted in FIG. 7, the annular guard ring is formed around the TSV with TSV fill 56 and extends from the top surface of the semiconductor structure (e.g., the top surface of front side interconnect wiring 10) to the top surface of substrate 2.

FIG. 8 depicts a cross-sectional view of the semiconductor structure after forming front side interconnect wiring, etching a trench for a multilayer annular guard ring, and then, depositing a first layer of a liner material, depositing a first dielectric material on the first layer of a liner material, a second layer of a liner metal material on the first dielectric material, and a second dielectric material for the multilayer annular guard ring, in accordance with an embodiment of the present invention. As depicted, FIG. 8 includes the elements of FIG. 3 with liner 84 deposited on the top surface of the semiconductor structure and in the trench, with dielectric 83 directly on liner 84, with liner 94 directly on dielectric 83, and dielectric 93 filling the remaining opening in the trench between the sidewalls and the bottom of liner 94.

As known to one skilled in the art, the semiconductor structure of FIG. 8 can be formed starting with a semiconductor structure that is essentially the same as the semiconductor structure of FIG. 3 using similar process steps as previously discussed with respect to FIGS. 3 through FIG. 7.

As depicted in FIG. 8, the trench can be formed around the center portion of ILD 3 without metal layers 9 or vias 6 in FIG. 8. In some cases, the trench depicted in FIG. 8 can be wider than the trench etched in FIG. 3. For example, the aspect ratio of the etched trench in FIG. 8 can typically range from 2.5 to 4 but is not limited to these aspect ratios. As previously discussed, the aspect ratio is the ratio between the depth of a hole and the diameter of a hole where the diameter of the hole, where, in this case, the diameter would be the width of the trench etched around the center of ILD 3 in the middle of FIG. 8. For example, to accommodate the additional liner layers and the additional dielectric materials of FIG. 8 compared the annular guard ring of FIG. 6, multilayer annular guard ring composed of liner 84, dielectric 83, liner 94, and dielectric 93 depicted in FIG. 8 can, in some cases, require a trench with a slightly wider width.

In various embodiments, liner 84 and liner 94 are each composed of a liner material. Liner 84 and liner 94 can be composed of the same or different liner materials. Each of liner 84 and liner 84 can be composed of one of the liner materials previously discussed for liner 34 with respect to FIG. 1. For example, liner 84 and liner 94 can be composed of one or more of the SiN materials mentioned previously. As previously discussed with respect to FIG. 4, liner 34, each of liner 84 and liner 94 can be deposited, for example, by a high-density plasma process such as CVD or ALD but are not limited to these deposition processes. In a typical example, the thickness of liner 84 and liner 94 can range from 50 to 100 nm but is not limited these thicknesses.

As depicted in FIG. 8, liner 84 is deposited over the top surface of the semiconductor structure including on exposed portions of front side interconnect wiring 10, on the sidewalls of ILD 3 in the trench etched around the center portion of ILD 3, and on the top exposed surface of substrate 2 in the trench. In FIG. 8, a layer of dielectric 83 is deposited on liner 84.

Using a deposition process such as PECVD, SACVD, ALD, or a flowable oxide material, dielectric 83 can be deposited directly on liner 84 and later, dielectric 93 can be deposited on liner 94. The thickness of dielectric 83 can range from ten to five hundred nm but is not limited to these thicknesses. In some embodiments, dielectric 83 and dielectric 93 are composed of the same dielectric material. In other embodiments, dielectric 83 and dielectric 93 are different dielectric materials. Dielectric 83 and dielectric 93 can be suitable dielectric material used in semiconductor chip formation.

Dielectric 93 can be deposited with one or more of the deposition processes above to fill the gap between the sidewall of liner 94 and to cover the portions of liner 94 above front side interconnect wiring 10 exposed on the top surface of the semiconductor substrate. In various embodiments, dielectric 93 fills the gap or opening between the sidewall of liner 94, covers the bottom surface of liner 94 in the trench, and the top surfaces of the semiconductor structure (e.g., over front side interconnect wiring 10 and ILD 3).

As depicted in FIG. 8, liner 84, dielectric 83, liner 94, and dielectric 93 each inside the trench around the center ILD 3 and on the top surfaces of the semiconductor structure (e.g., over front side interconnect wiring 10 and ILD 3).

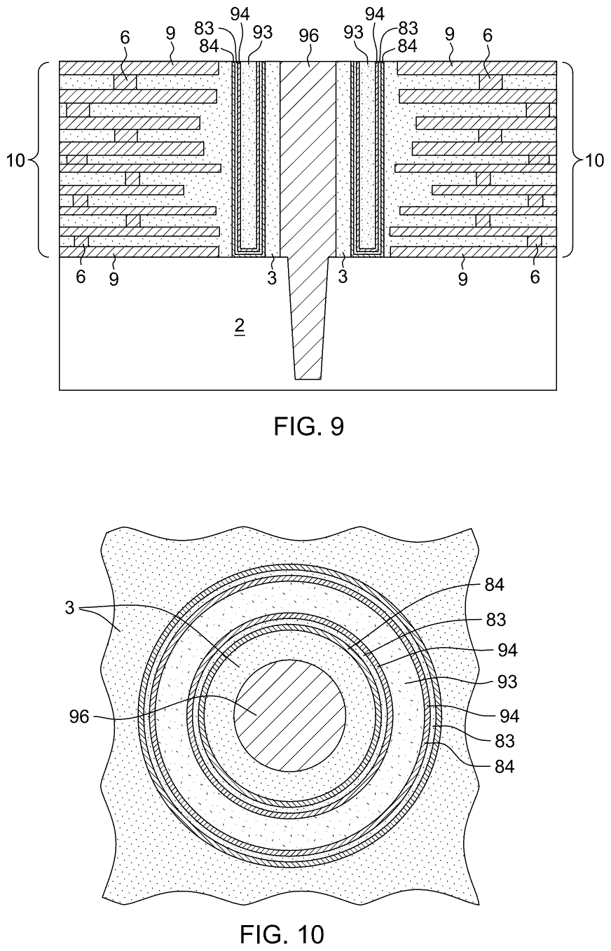

FIG. 9 depicts a cross-sectional view of the semiconductor structure after performing as CMP, etching a top portion of a TSV via hole in ILD 3, etching a bottom portion of the TSV via hole in semiconductor substrate 2, and filling the TSV via hole with TSV fill 96, in accordance with an embodiment of the present invention.

In various embodiments, a CMP removes the horizontal portions of liner 84, dielectric 83, liner 94, and dielectric 83 on the top surface of the semiconductor structure. As depicted in FIG. 9, the CMP exposes the top surface of front side interconnect wiring 10, a portion of ILD 3, the top surfaces of liner 84 on the sidewall of the trench, the top surfaces of dielectric 83, the top surfaces of liner 94, the top surface of dielectric 93, and the top surface of an inner ring of ILD 3 in the center of FIG. 9.

After planarizing the top surface of the semiconductor structure, the top portion of a TSV via hole can be etched in the center of FIG. 9 above the top surface of substrate 2. The top portion of the TSV via hole is etched through ILD 3 stopping on the top surface of semiconductor substrate 2 using known BEOL etching processes (e.g., patterning and RIE) for forming the top portion of a via last TSV via hole. After completing the etch of the top portion of the TSV via hole, a portion of ILD 3 remains around the sidewall of the top portion of the TSV via hole. The ring-like remaining portion of the center ILD 3 is between the top portion of the TSV via hole and liner 34. The remaining portion of the center ILD 3 can electrically isolate liner 84 from the future TSV.

After etching the top portion of the TSV via hole above semiconductor substrate 2, using known TSV semiconductor etching processes (e.g., RIE, IBE, and/or wet semiconductor etching process), the bottom portion of the TSV via hole is formed in semiconductor substrate 2. In various embodiments, the bottom portion of the TSV via hole does not extend to the bottom surface of semiconductor substrate 2 (e.g., forms a blind via hole). As depicted, the bottom portion of the TSV via hole extends from the top surface of semiconductor substrate 2 to the bottom region of semiconductor substrate although in other examples, the depth of the bottom portion of the TSV via hole may be less or greater than the depth of the TSV via hole in FIG. 9.

Using known TSV fill fabrication processes, the TSV via hole can be filled with a conductive metal fill such as, but not limited to, copper. As known to one skilled in the art, the process of filling the TSV via hole with TSV fill 96 includes depositing at least a TSV insulating liner (not depicted) on exposed surfaces of the TSV via hole, a barrier layer (not depicted), a seed layer (not depicted) on the TSV insulating liner, and TSV fill 96 deposited on the seed layer. In FIG. 9, TSV fill 96 can include at least a TSV insulating liner (not depicted), barrier layer (not depicted), seed layer (not depicted), and conductive metal fill (e.g., copper) fill the TSV via hole. TSV fill 96 is typically copper but may be a different electrically conductive material. TSV fill 96 fills the TSV via hole as depicted in FIG. 9. TSV fill 96 can be deposited by one or more known deposition processes (e.g., ALD, CVD, PVD, PECVD, electroplating or a combination of these) inside the TSV via hole. A CMP may be performed to planarize the top surface of the semiconductor structure and remove any excess TSV fill 56.

As depicted, TSV fill 96 resides inside a ring of the remaining portion of the center ILD 3. The ring of the remaining center ILD 3 separates and electrically isolates liner 84 from TSV fill 56. The multilayer annular guard ring composed of liner 84, dielectric 83, liner 94, and dielectric 93 resides directly on the top surface of semiconductor substrate 2. The multilayer annular guard ring reduces or prevents the moisture or any semiconductor substrate 2 etching chemicals from entering the layers of front side interconnect wiring 10 during the etching of the bottom portion of TSV via hole and the various subsequent deposition processes for creating TSV fill 96. As depicted in FIG. 9, the multilayer annular guard ring is formed around the TSV with TSV fill 96 and extends from the top surface of the semiconductor structure (e.g., the top surface of front side interconnect wiring 10) to the top surface of semiconductor substrate 2.

While not depicted, as known to one skilled in the art, the TSV may be completed by attaching a carrier wafer, performing a wafer flip, and grinding the backside of semiconductor substrate 2 to expose a bottom surface of TSV fill 96.

FIG. 10 depicts a top view of the multilayer annular guard ring in a center portion of the semiconductor structure of FIG. 9, in accordance with an embodiment of the present invention. As depicted, FIG. 9 includes the elements of FIG. 8 without the horizontal portions of liner 84, dielectric 83, liner 94, and dielectric 93 on the top surface of the semiconductor structure.

As depicted in FIG. 10, a number of concentric rings of various dielectric materials (e.g., ILD 3, dielectric 83, and dielectric 93) and a number of concentric rings of liner materials (e.g., liner 84 and liner 94) around TSV fill 96 of a TSV. The concentric rings can be formed by sequentially depositing liner 84, then dielectric 83 on liner 84, depositing liner 94 on dielectric 83, and then filling the opening inside liner 94 with dielectric 93 to create the multilayer annular guard ring depicted in the top view of the semiconductor structure of FIG. 9. As previously discussed, the multilayer annular guard ring extends from the top surface depicted in FIG. 10 through front side interconnect wiring 10 as depicted in FIG. 9 to the top surface of semiconductor substrate 2.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
an annular guard ring extending through an interlayer dielectric (ILD) layer to a top surface of a semiconductor substrate, wherein:
the annular guard ring surrounds a through-silicon-via (TSV); and
the annular guard ring is composed of layer of a liner material around a dielectric material.

2. The semiconductor structure of claim 1, wherein the liner material is a nitride.

3. The semiconductor structure of claim 1, wherein the dielectric material is an oxide.

4. The semiconductor structure of claim 1, wherein the annular guard ring extends through the ILD to a top surface of the ILD.

5. The semiconductor structure of claim 1, wherein the dielectric material is a core of the annular guard ring, such that the liner material is present on a bottom surface of the dielectric material and sidewalls of the dielectric material.

6. The semiconductor structure of claim 1, wherein ILD material is present between the TSV and the annular guard ring.

7. The semiconductor structure of claim 1, wherein the annular guard ring is only present in a back-end-of-line (BEOL) level.

8. A semiconductor structure comprising:
an annular guard ring extending through an interlayer dielectric (ILD) layer to a top surface of a semiconductor substrate, wherein:
the annular guard ring surrounds a through-silicon-via (TSV); and
the annular guard ring is composed of a first liner layer, a first dielectric material layer, a second liner layer, and a second dielectric material.

9. The semiconductor structure of claim 8, wherein the first liner layer is a nitride.

10. The semiconductor structure of claim 8, wherein the second liner layer is a nitride.

11. The semiconductor structure of claim 8, wherein the first dielectric material is an oxide.

12. The semiconductor structure of claim 8, wherein the second dielectric material is an oxide.

13. The semiconductor structure of claim 8, wherein the annular guard ring extends through the ILD to a top surface of the ILD.

14. The semiconductor structure of claim 8, wherein ILD material is present between the TSV and the annular guard ring.

15. The semiconductor structure of claim 8, wherein the annular ring is only present in a back-end-of-line (BEOL) level.

16. The semiconductor structure of claim 8, wherein the first dielectric material is a core of the annular guard ring, such that the first liner material is present on a bottom surface of the dielectric material and sidewalls of the first dielectric material.

17. The semiconductor structure of claim 16, wherein the second dielectric material is present on a bottom surface of the first liner material and sidewalls of the first liner material.

18. The semiconductor structure of claim 17, wherein the second liner material is present on a bottom surface of the second dielectric material and sidewalls of the second dielectric material.

19. A method comprising:
forming an annular trench within an interlayer dielectric (ILD) layer, wherein the annular trench exposes a top surface of a substrate;
forming a liner material layer on exposed surfaces of the ILD layer and the substrate;
removing portions of the liner material layer that are external to the annular trench; and
forming a dielectric material layer within the annular trench.

20. The method of claim 19, further comprising:
forming a second liner material layer within the annular trench on exposed surfaces of the dielectric material layer; and
forming a second dielectric layer within the annular trench on exposed surfaces of the second liner material layer.
